(19) United States
(12) Patent Application Publication
(10) Pub. No.: US 2012/0058588 A1
(43) Pub. Date: Mar. 8, 2012

(54) DEVICE AND METHOD FOR SIMULTANEOUSLY MICROSTRUCTURING AND DOPING SEMICONDUCTOR SUBSTRATES

(75) Inventors: Kuno Mayer, Freiburg (DE); Ingo Krossing, Freiburg (DE); Carsten Knapp, Freiburg (DE); Filip Granek, Wroclaw (PL); Matthias Mesec, Freiburg (DE); Andreas Rodofili, Freiburg (DE)

(73) Assignee: FRAUNHOFER-GESELLSCHAFT zur Forderung der angewandten Forschung e.V., Munich (DE)

(21) Appl. No.: 13/223,379

(22) Filed: Sep. 1, 2011

Related U.S. Application Data
(63) Continuation of application No. PCT/EP2010/000918, filed on Feb. 15, 2010.

(30) Foreign Application Priority Data
Mar. 2, 2009 (DE) 102009011308.8

(51) Int. Cl. H01L 21/22; B05B 1/00; B05B 15/00; C07F 5/05

(52) U.S. Cl. 438/57; 438/542; 548/405; 548/110; 118/620; 257/E21.135

(57) ABSTRACT

The invention relates to a device and a method for simultaneous microstructuring and doping of semiconductor substrates with boron, in which the semiconductor substrate is treated with a laser beam coupled into a liquid jet, the liquid jet comprising at least one boron compound. The method according to the invention is used in the field of solar cell technology and also in other fields of semiconductor technology in which a locally delimited boron doping is important.

### PRIORITY INFORMATION

The present application is a continuation of PCT Application No. PCT/EP2010/000918, filed on Feb. 15, 2010, that claims priority to German Application No. 102009011308.8, filed on Mar. 2, 2009, both of which are incorporated herein by reference in their entireties.

### BACKGROUND OF THE INVENTION

The invention relates to a device and a method for simultaneous microstructuring and doping of semiconductor substrates with boron, in which the semiconductor substrate is treated with a laser beam coupled into a liquid jet, the liquid jet comprising at least one boron compound. The method according to the invention is used in the field of solar cell technology and also in other fields of semiconductor technology in which a locally delimited boron doping is important.

In the case of boron doping known from the state of the art in solar cell production, a boron source is applied on the region of the surface to be doped, said source generally concerning a boron-oxygen compound, such as for instance boric acid B(OH)₃ or condensation products of orthoboric acid, such as for instance disodium tetraborate (Na₂B₄O₇). Application of the boron source is effected from aqueous solution. The solvent is evaporated with subsequent tempering. The boron source vitrifies on the substrate surface with formation of a borosilicate glass. With selective heating of this glass layer, boron atoms diffuse into the substrate surface and produce the desired doping there.

The boron source (the borosilicate glass) is removed after conclusion of the doping process from the substrate surface by an etching step subsequent to the doping process.

In order to avoid whole-surface doping of the substrate surface, for instance when only those regions of the substrate surface on which subsequently metal contacts are applied are intended to be doped, firstly application of etching masks on the substrate surface is required, which enable access of the boron source only to those regions which are intended to be doped. Application and subsequent removal of these etching masks is associated with additional process steps.

This method has however the following disadvantages:
1. Borosilicate glass represents an extremely oxygen-rich boron source. The boron doping with the help of borosilicate glass has the serious disadvantage that, in parallel to the boron diffusion, also an oxygen diffusion into the substrate is effected. Oxygen atoms in the silicon substrate can have an extremely negative effect on the electrical properties of the semiconductor, in particular in the region of the p-n junction of the solar cell.
2. The boron-oxygen bond is overall one of the most stable covalent bonds, the B-O dissociation energy is correspondingly very high and demands processing at relatively high process temperatures. These in turn also promote wide diffusion of impurities, which are present in the system, into the substrate.
3. Operating with etching masks for prevention of a whole-surface doping of the substrate represents a significant additional complexity in the solar cell processing, caused by the increase in the number of partial process steps.
4. Etching masks are furthermore a further contamination source for the substrate to be processed.

### SUMMARY OF THE INVENTION

Starting herefrom, it was the object of the present invention to provide a method which avoids the mentioned disadvantages of the state of the art and makes possible a method for doping semiconductors which is easy to handle and rapid.

This object is achieved by the method having the features of claim 1, the boron compounds having the features of claims 21 and 22 and also the device having the features of claim 23. The further dependent claims reveal advantageous developments.

According to the invention, a method for simultaneous microstructuring and doping of semiconductor substrates is provided, in which a liquid jet which is directed towards the substrate surface and comprises at least one boron compound as dopant is guided over the regions of the substrate to be structured, a laser beam being coupled into the liquid jet, as a result of which the substrate surface is heated locally by the laser beam and consequently is structured at least in regions and, in the structured regions, diffusion of boron atoms into the semiconductor substrate is effected.

The method according to the invention thereby has the following advantages:
1. The invention enables selective boron doping with simultaneous microstructuring of silicon substrates in a single process step and a reduction in the process time for the doping process in the sub-second range.
2. The method described here represents a significant simplification in the technical outlay for the boron doping.
3. The new doping process thereby dispenses with the disadvantageous boron source, borosilicate glass.
4. The method enables, for the first time, the production of an n-type solar cell based on multicrystalline silicon.

There are used preferably as boron compound, compounds in which the boron atoms are not bonded covalently to oxygen atoms, but preferably to hydrogen or to further boron atoms. These compounds have low dissociation energies and circumvent the disadvantage of a cross-contamination of the substrate by oxygen atoms which is effected in parallel to the doping process. The boron compounds are preferably selected from the group consisting of alkali boron hydrides, diboranes, polyboranes, boron hydride clusters is which covalent (multicentred) bonds are present exclusively between boron atoms amongst each other or boron atoms and hydrogen atoms, the clusters being able to be present either electrically neutral or in ionic form as anions. The cations for the anionic boron clusters are preferably selected from the group of alkali metals, and also some organic compound classes, such as for instance tertiary or quaternary alkyl- or (alkyl)phenyl phosphonium salts, tertiary alkyl- or (alkyl)phenyl sulphonium salts, pyrimidinium ions, morpholinium ions, piperidinium ions, imidazolinium ions, pyrrolodinium ions and further heterocyclic derivates of the mentioned compounds.

The organic cations for the boron clusters have the following structures for particular preference:

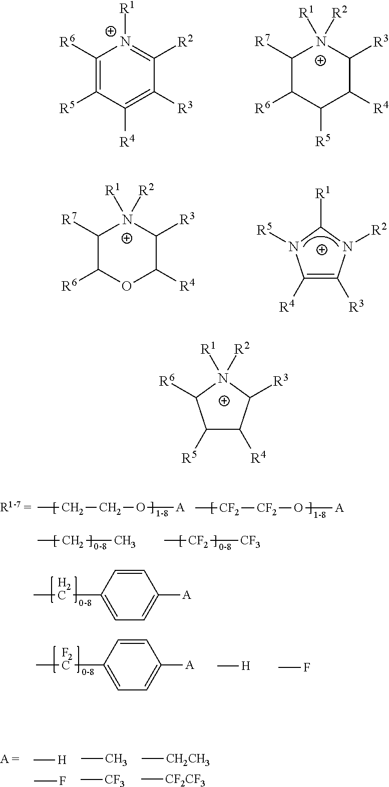

For particular preference, the boron compounds are selected from the group consisting of alkali boron hydrides (M[BH₄] with M=cation of the alkali metals), alkali salts of the dodecahydrododecaborates (M[B₁₂H₁₂]), butyldimethylpyrrolidinium octahydrotriborate, butyldimethylimidazolinium octahydrotriborate and mixtures hereof.

The liquid jet used according to the invention can comprise both at least one boron compound and consist of at least one boron compound.

Preferably, the liquid jet consists of a binary system which comprises, on the one hand, a solvent which serves as carrier for the boron compound and the actual boron compound.

In a further preferred embodiment, the liquid jet comprises, in addition to a boron compound, also an aluminium compound which likewise concerns a hydrogen compound of the element of the 3^{rd} main group, e.g.: lithium aluminium hydride (LiAlH₄). Both binary and ternary systems are thereby possible.

A preferred variant of a binary system provides as liquid medium an ionic liquid comprising boron, e.g.: butyldimethylimidazolinium octahydrotriborate in which an aluminium compound, e.g.: LiAlH₄, is dissolved.

A preferred variant of a ternary system provides as liquid medium an ionic liquid comprising boron, in which both a boron and an aluminium source are dissolved.

In addition to lithium aluminium hydride, in principle all compounds of aluminium, in which the aluminium atom is not bonded to oxygen, are possible. Particularly preferred aluminium compounds are however aluminium compounds in which the aluminium atom is bonded covalently to hydrogen atoms, such as in the case of lithium aluminium hydride, further aluminium atoms, such as in the case of Al₂H₆ dimer, or to carbon atoms, such as in the case of tetraalkylaluminates.

A possible solvent for boron compounds is water which however comprises oxygen which is regarded as disadvantageous for the doping process. Oxygen-free alternatives come from the range of organic solvents, in particular perfluorinated carbon compounds. There are included herein for example perfluorohexane, perfluoroheptane, perfluorotritertbutylamine, perfluorodecaline and various perfluoro-N-alkyl morpholines, e.g. perfluoro-N-propylmorpholine. These perfluorinated carbon compounds have a low tendency to decompose and have very high gas solubility so that these are particularly suitable for gaseous boron compounds, e.g. diborane.

A further preferred solvent class with a small quantity of covalently bonded oxygen are poorly flammable ethers, e.g. ethyl-tert-butylether or di-tert-butylether. They are suitable preferably as solvents for ionic liquids comprising boron.

A further system provides an organic compound as solvent which has one or more hetero atoms, such as for instance oxygen or sulphur which have free electron pairs. The molecules of the solvent form, with the boron source which concerns monoborane, a Lewis acid base adduct. Such systems are for instance the borane tetrahydrofuran complex and the borane dimethylsulphide complex:

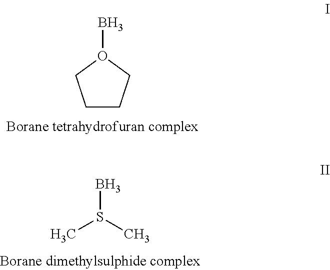

The method according to the invention uses a laser beam which is coupled into a liquid jet and preferably is conducted towards the substrate surface by total reflection on the inner wall of the liquid jet, where it causes a locally delimited heating of the surface. The liquid jet thereby serves as liquid light guide of a variable length for the laser beam which remains focused as long as the liquid jet maintains its compact beam length and its laminarity. Likewise, the liquid jet assumes the task of transporting the etching media to the process hearth on the substrate surface.

The laser beam has a double task: on the one hand, it ensures the thermal removal of the substrate provided that this is desired and, on the other hand, it enables decomposition of the boron source in the region of the laser spot due to its thermal effect.

The liquid jet generally has a diameter of 10 to 500 μm, however preferably of 20 to 100 μm. Heating of the substrate surface with the help of the laser beam remains preferably delimited to the beam diameter of the liquid jet. Beyond the beam focus, the substrate surface has an ambient temperature of generally 25° C. In this way, the locally highly selective processing of the substrate surface becomes possible for the first time.

In the hot focusing region of the laser beam/liquid jet, the melting temperature of the silicon can be exceeded however. Under these conditions, the substances applied on the substrate surface by the liquid jet decompose into their atoms which then diffuse into the substrate.

The liquid jet has a high flow velocity, generally between 20 and 500 m/s and thereby develops an important mechanical impetus which transports the waste products of the process swiftly from the reaction hearth.

Two nozzles which are directed directly towards the substrate surface assume the cleaning of the substrate surface. One nozzle rinses the reaction hearth radially with deionised water, the other, which concerns a compressed air fan, removes the liquid film from the surface.

The maximum travel speed of the substrate holder relative to the laser beam/liquid jet is up to 1,000 mm/s.

According to the invention, boron compounds are likewise provided according to formulae III and IV.

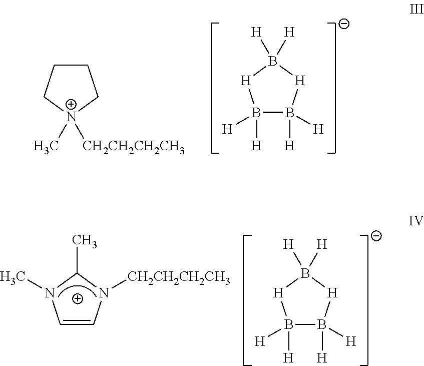

These compounds make possible a particularly efficient and rapid implementation of the method according to the invention.

According to the invention, a device for implementing the method, as was described previously, is likewise provided, which has a nozzle unit with a window for coupling in a laser beam, a laser beam source, a liquid supply for at least one boron compound as dopant and a nozzle opening directed towards a surface of the substrate.

In a first variant, the nozzle unit and the laser beam source are coupled to a guide device for controlled guidance of the nozzle unit over the surface to be structured.

In a further alternative, the nozzle unit and the laser beam source are stationary and the substrate is coupled to a guide device for controlled guidance of the substrate relative to the nozzle unit and the laser beam source.

The method according to the invention is used in particular in the production of solar cells or in the case of other machining or processing methods for semiconductors.

The subject according to the invention is intended to be explained in more detail with reference to the subsequent examples and Figures without wishing to restrict said subject to the special embodiments shown here.

### DETAILED DESCRIPTION OF THE ILLUSTRATED EMBODIMENT

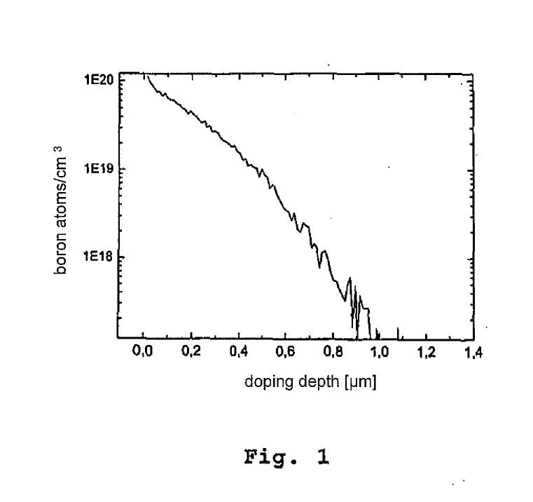

FIG. 1 shows a depth profile of the boron atom concentration in a doped region by means of an SIMS measurement in a diagram.

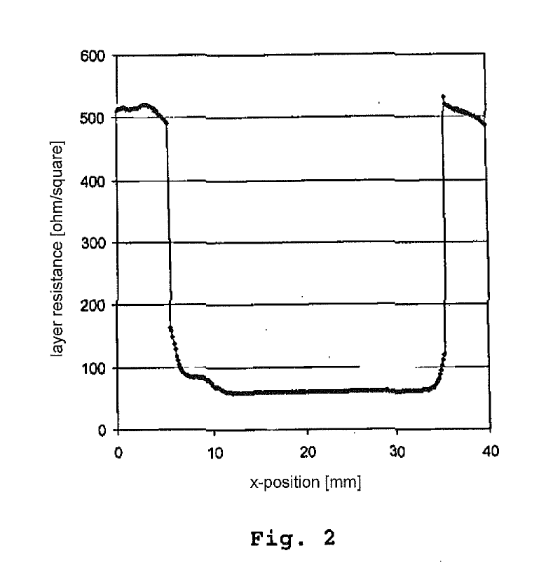

FIG. 2 shows, with reference to a diagram, a four-peak measurement of a 30×30 mm² field which consists of 1,500 LCP lines doped with boron at a 20 μm spacing. The average laser power here was 0.6 W, the speed 50 mm/s and the laser frequency 35 kHz.

### EXAMPLE 1

An embodiment of the invention provides highly pure water as solvent, in which sodium- or potassium boron hydride (NaBH₄ or KBH₄) is dissolved as boron source. The solution has a pH value of 14. In this state, both substances are stable in aqueous solution. The concentration of both species is for example 12% by weight. A frequency-doubled Nd:YAG laser of wavelength 532 nm and the power of 2 watts serves as laser light source. The flow velocity of the liquid jet is for example 150m/s. The travel speed of the substrate relative to the liquid jet is 200 mm/s.

A surface processed in this way having a surface resistance of 520 ohm/square before the processing has, after the processing, a surface doping concentration of above 10²⁰ boron atoms/cm³ and a surface resistance of 60 ohm/square with a track spacing of 20 μm. Surface resistance measurement of the processed region (width: 30 mm) and depth doping profile of a processed track are represented in FIG. 1 and FIG. 2.

### EXAMPLE 2

A further embodiment of the invention likewise provides highly pure water as solvent. Potassium dodecahydrododecaborate (K₂B₁₂H₁₂) serves here as boron source. The solution has a pH value of 12. The concentration of the boron source in solution is also here 10% by weight. A frequency-doubled Nd:YAG laser of wavelength 532 nm and the power of 4 watts thereby serves as laser light source. The flow velocity of the liquid jet is for example 100m/s. The travel velocity of the substrate relative to the liquid jet is 50 mm/s.

### EXAMPLE 3a

A further embodiment provides methylene chloride as solvent for the boron source. Butyldimethylimadazolinium octahydrotriborate (BDMIM⁺ B₃H₈⁻) serves here as boron source. The concentration of the boron source is 1 mol/l. Alternatively, butylmethylpyrrolidinium octahydrotriborate (BMP⁺ B₃H₈⁻) can also be used as boron source. A frequency-doubled Nd:YAG laser of wavelength 532 nm and the power of 2 watts thereby serves as laser light source. The flow velocity of the liquid jet is for example 100m/s. The travel speed of the substrate relative to the liquid jet is 50 mm/s.

### EXAMPLE 3b

In a further embodiment, a solvent is entirely dispensed with since the boron sources mentioned in example 3a are liquids under standard conditions. They can therefore also serve directly as jet medium without further supplements.

The experimental parameters in this case are the same as those in example 3a.

### EXAMPLE 3c

In a further embodiment, butyldimethylimidazolinium octahydrotriborate (BDMIM⁺ B₃H₈⁻) is used as solvent. The solvent is at the same time also a boron source. Also NaBH₄ is found dissolved in solution as additional boron source. The concentration of NaBH₄ in the solution is 0.5 mol/l.

The experimental parameters in this case are also the same as those in example 3a.

Instead of NaBH₄, also diborane B₂H₆ can be used optionally as additional boron source, which is soluable likewise to a limited extent in the ionic liquid, e.g. in a concentration of 0.01 mol/l.

### EXAMPLE 4

A further embodiment provides a mixture of perfluoro-tri-tertbutylamine and perfluorodecaline as solvent. Diborane which is dissolved in gaseous form in the mentioned liquid mixture in the concentration 0.05 mol/l serves here as boron source. A frequency-doubled Nd:YAG laser of wavelength 532 nm and the power of 2 watts thereby serves as laser light source. The flow velocity of the liquid jet is for example 100m/s. The travel speed of the substrate relative to the liquid jet is 50 mm/s.

What is claimed is:

1. A method for simultaneous microstructuring and doping of semiconductor substrates, in which a liquid jet which is directed towards the substrate surface and comprises at least one boron compound as dopant is guided over the regions of the substrate to be structured, a laser beam being coupled into the liquid jet, as a result of which the substrate surface is heated locally by the laser beam and consequently is structured at least in regions and, in the structured regions, diffusion of boron atoms into the semiconductor substrate is effected.

2. The method according to claim 1,
wherein the boron compound is selected from the group consisting of alkali boron hydrides, diboranes, polyboranes, boron hydride clusters is which covalent (multicentred) bonds are present exclusively between boron atoms amongst each other or boron atoms and hydrogen atoms, the clusters being able to be present either electrically neutral or in ionic form as anions.

3. The method according to claim 2,
wherein the cations for the anionic boron clusters are selected from the group of tertiary or quaternary alkyl- or (alkyl)phenyl ammonium salts, tertiary or quaternary alkyl- or (alkyl)phenyl phosphonium salts, tertiary alkyl- or (alkyl)phenyl sulphonium salts, pyrimidinium ions, morpholinium ions, piperidinium ions, imidazolinium ions, pyrrolodinium ions and further heterocyclic derivates of the mentioned compounds.

4. The method according to claim 3,
wherein the cations for the boron clusters have the following structural frameworks:

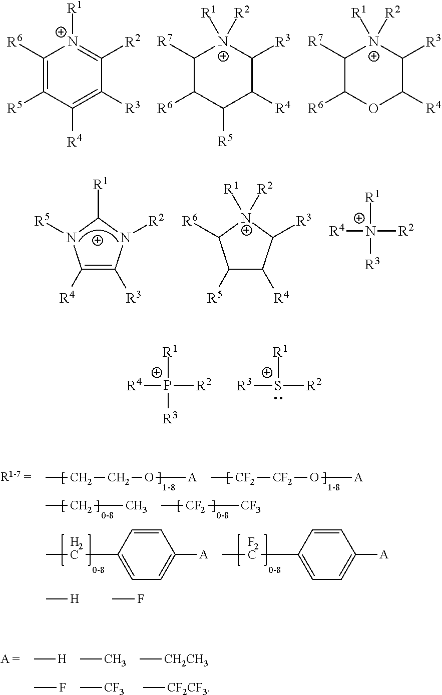

5. The method according claim 1,
wherein the boron compound is selected from the group consisting of alkali boron hydrides, alkali dodecahydrododecaborates, butyldimethylpyrrolidinium octahydrotriborate, butyldimethylimidazolinium octahydrotriborate and mixtures hereof.

6. The method according to claim 1, wherein the boron compound is dissolved in an aqueous or organic solvent.

7. The method according to claim 6,
wherein the solvent is essentially free of bonded oxygen atoms, preferably perfluorinated carbon compounds and particularly preferred perfluorohexane, perfluoroheptane, perfluorotritertbutylamine, perfluorodecaline and perfluoro-N-propylmorpholine.

8. The method according to claim 6,
wherein the solvent is selected from the series of poorly flammable ethers, preferably di-tert-butylether and ethyl-tert-butlyether.

9. The method according to claim 6,
wherein the solvent is an organic compound which forms, with the boron compound, Lewis acid base adducts, in particular according to formulae I and II.

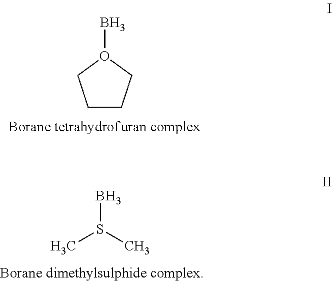

10. The method according to claim 1,
wherein the liquid jet comprises in addition an aluminium compound.

11. The method according to claim 10,
wherein the aluminium compound is selected from the group of aluminium compounds in which the aluminium atom is bonded covalently exclusively to hydrogen atoms, further aluminium atoms or carbon atoms.

12. The method according to claim 11,
wherein the aluminium compound is sodium aluminium hydride, Al₂H₆ or a tetraalkylaluminate.

13. The method according to claim 1, wherein the laser beam is guided in the liquid jet by total reflection and the liquid jet is preferably laminar.

14. The method according to claim 1, wherein the liquid jet has a diameter in the range of 10 to 500 μm, in particular of 20 to 100 μm.

15. The method according to claim 1, wherein the local heating of the substrate surface is delimited on the substrate surface to the region defined by the liquid jet.

16. The method according to claim 1, wherein local heating of the substrate surface is effected such that a dissociation of the at least one boron compound is effected.

17. The method according to claim 1, wherein the substrate is selected from the group consisting of silicon, glass, silicon-containing ceramics and composites thereof.

18. The method according to claim 1, wherein the structuring is an edge insulation of a silicon solar cell, in particular for a rear-side-contacted or subsequently metallised solar cell.

19. The method according to claim 1, wherein the doping which is produced provides production of a highly positively (p⁺) doped emitter in a semiconductor component, in particular a solar cell.

20. The method according to claim 15,
wherein the highly p⁺-doped emitter serves as diffusion barrier for a contact metal deposited thereon.

21. Boron compound of formula III:

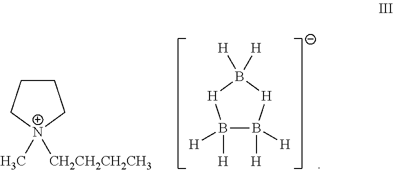

22. Boron compound of formula IV:

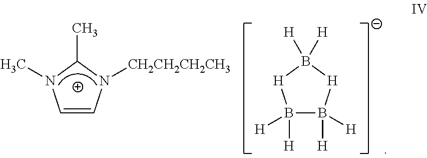

23. A device for implementing the method according to claim 1 comprising a nozzle unit having a window for coupling in a laser beam, a laser beam source, a liquid supply for at least one boron compound as dopant and a nozzle opening directed towards a surface of the substrate.

24. The device according to claim 23,
wherein the nozzle unit and the laser beam source is coupled to a guide device for controlled guidance of the nozzle unit over the surface to be structured.

25. The device according to claim 23,
wherein the nozzle unit and the laser beam source are stationary and the substrate is coupled to a guide device for controlled guidance of the substrate relative to the nozzle unit and the laser beam source.
